(19) United States
(12) Patent Application Publication
(10) Pub. No.: US 2009/0026529 A1
(43) Pub. Date: Jan. 29, 2009

(54) SEMICONDUCTOR DEVICE AND METHOD FOR MANUFACTURING THE SAME

(76) Inventor: Hiroshi AKAHORI, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/179,700

(22) Filed: Jul. 25, 2008

(30) Foreign Application Priority Data
Jul. 25, 2007 (JP) 2007-193614

(51) Int. Cl. H01L 29/792; H01L 21/336

(52) U.S. Cl. 257/324; 257/330; 438/261; 438/287; 257/E21.409; 257/E29.309

(57) ABSTRACT

A semiconductor device includes a silicon substrate having a main surface, the main surface including a region in which a groove structure or a concavity and convexity structure is formed, and a nonvolatile memory cell provided on the main surface of the silicon substrate, the nonvolatile memory cell including a first insulating film as a tunnel insulating film provided on the region, a charge storage layer provided on the first insulating film, a second insulating film provided on the charge storage layer, a control gate provided on the second insulating film.

### CROSS-REFERENCE TO RELATED APPLICATIONS

This application is based upon and claims the benefit of priority from prior Japanese Patent Application No. 2007-193614, filed Jul. 25, 2007, the entire contents of which are incorporated herein by reference.

### BACKGROUND OF THE INVENTION

1. Field of the Invention

The present invention relates to a semiconductor device comprising nonvolatile memory cell including a tunnel insulating film and method for manufacturing the same.

2. Description of the Related Art

In a nonvolatile semiconductor memory device of floating gate type or MONOS type, miniaturization of the memory cells has been proceeded. However, reduction of program voltage is not in progress. Problems such as an increasing of mutual potential interferences between the cells or an increasing of breakdown voltage necessary for between the cells occurs when the program voltage is not reduced.

Thinning of the tunnel insulating film has been proposed as a technique for reducing the program voltage.

However, thinning of the tunnel insulating film is accompanied by degradation of the charge retention characteristic. This is the phenomenon that threshold voltage of the transistor changes because the charges in the charge accumulation layer is lost when the transistor is left for a long time after setting the threshold voltage of the transistor to a predetermined value by injecting electrons into the charge accumulation layer. In the case of n-channel transistors, there arises a change that the threshold voltage falls.

The change of the threshold voltage becomes more remarkable when the tunnel insulating film is made thinner. In the case of a large scale memory array, defective cells having changed threshold voltage exist by a scale of several hundreds to thousand bits. The probability of appearance of the defective cell remarkably rises as the tunnel insulating film is made thinner.

In this manner, the thinning of the tunnel insulating film causes the degradation of charge retention characteristic. Therefore, the thinning of the tunnel insulating film that is the mean for solving the problem cannot be adopted readily in order to lower the program voltage at present.

In addition, Naruke et al. describe the risk of occurrence of SILC (stress induced leakage current) by thinning of the tunnel insulating film in the reference (“Stress induced leakage current limiting to scale down EEPROM tunnel oxide thickness”, in IEDM Technical Digest., 1988, pp. 424-427). The initial J-E characteristic illustrated in FIG. 1 of the above cited paper is dominated by FN (Fowler-Nordheim) tunneling current and shows an ideal characteristic in the case of silicon oxide film based tunnel insulating film. However, J-E characteristic after the stress is applied shows a degraded characteristic that electric current flows in relatively low electric field. This tendency becomes more remarkable when the thickness of the oxide film is reduced. This is the most significant factor that impedes the thinning of the tunnel insulating film. At present, the lower limit of the film thickness is 8 to 9 nm, and it is hard to make the tunnel insulating film thinner because the J-E characteristic of the tunnel insulating film is degraded.

### BRIEF SUMMARY OF THE INVENTION

According to an aspect of the present invention, there is provided a semiconductor device comprising: a silicon substrate having a main surface, the main surface including a region in which a groove structure or a concavity and convexity structure is formed; and

a nonvolatile memory cell provided on the main surface of the silicon substrate, the nonvolatile memory cell including a first insulating film as a tunnel insulating film provided on the region, a charge storage layer provided on the first insulating film, a second insulating film provided on the charge storage layer, a control gate provided on the second insulating film.

According to an aspect of the present invention, there is provided a method for manufacturing a semiconductor device comprising forming a groove structure or a concavity and convexity structure on a surface of a silicon substrate; and forming a nonvolatile memory cell on the main surface of the silicon substrate, the nonvolatile memory cell including a first insulating film as a tunnel insulating film provided on the region, a charge storage layer provided on the first insulating film, a second insulating film provided on the charge storage layer, a control gate provided on the second insulating film.

### BRIEF DESCRIPTION OF THE SEVERAL VIEWS OF THE DRAWING

FIG. 1 is a plane view of memory cell array of NAND type flash memory;

FIG. 2 is an equivalent circuit diagram of the memory cell array of the NAND type flash memory;

FIG. 3 is a cross-sectional view in a channel width direction showing a method for manufacturing a semiconductor device of an embodiment;

FIG. 4 is a cross-sectional view in the channel width direction showing the method for manufacturing the semiconductor device of the embodiment following the FIG. 3;

FIG. 5 is a cross-sectional view in the channel width direction showing the method for manufacturing the semiconductor device of the embodiment following the FIG. 4;

FIG. 6 is a cross-sectional view in the channel width direction showing the method for manufacturing the semiconductor device of the embodiment following the FIG. 5;

FIG. 7 is a cross-sectional view in the channel width direction showing the method for manufacturing the semiconductor device of the embodiment following the FIG. 6;

FIG. 8 is a cross-sectional view in the channel width direction showing the method for manufacturing the semiconductor device of the embodiment following the FIG. 7;

FIG. 9 is a cross-sectional view in the channel width direction showing the method for manufacturing the semiconductor device of the embodiment following the FIG. 8;

FIG. 10 is a cross-sectional view in the channel width direction showing the method for manufacturing the semiconductor device of the embodiment following the FIG. 9;

FIG. 11 is a cross-sectional view in the channel width direction showing the method for manufacturing the semiconductor device of the embodiment following the FIG. 10;

FIG. 12 is a cross-sectional view in the channel width direction showing the method for manufacturing the semiconductor device of the embodiment following the FIG. 11;

FIG. 13 is a cross-sectional view in a channel length direction showing the method for manufacturing the semiconductor device of the embodiment following the FIG. 12;

FIG. 14 is a cross-sectional view in the channel length direction showing the method for manufacturing the semiconductor device of the embodiment following the FIG. 13;

FIG. 15 is a schematic view showing electric lines of force at corner sections and flat sections of a tunnel insulating film when a negative high voltage is applied to a control gate electrode;

FIG. 16 is a view showing band structures of corner sections and flat sections of a tunnel insulating film when a negative high voltage and negative low voltage are applied to a control gate electrode;

FIG. 17 is a view showing FN current-voltage characteristics of comparative examples 1 and 2, and embodiment; and

FIGS. 18A and 18B show relationships between ratio (r/d) and applied voltage when FN current density reaches 1×10⁻³ A/cm² and a view for explaining the ratio (r/d).

### DETAILED DESCRIPTION OF THE INVENTION

Hereinafter, the embodiments of the present invention are described by referring to the drawings.

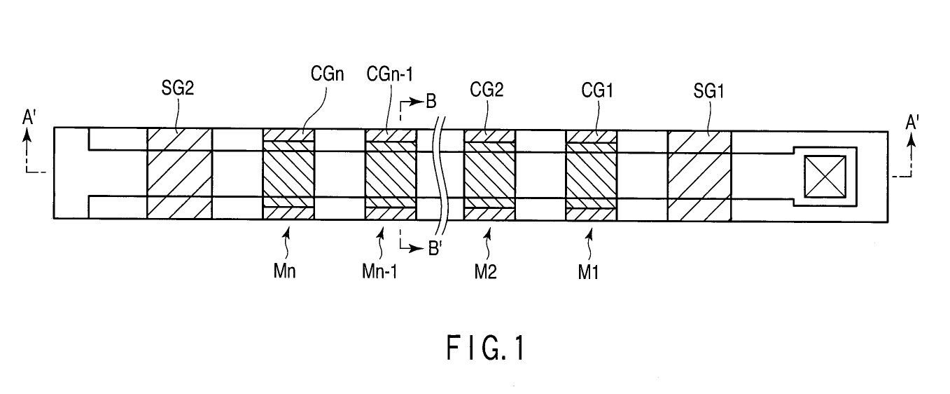

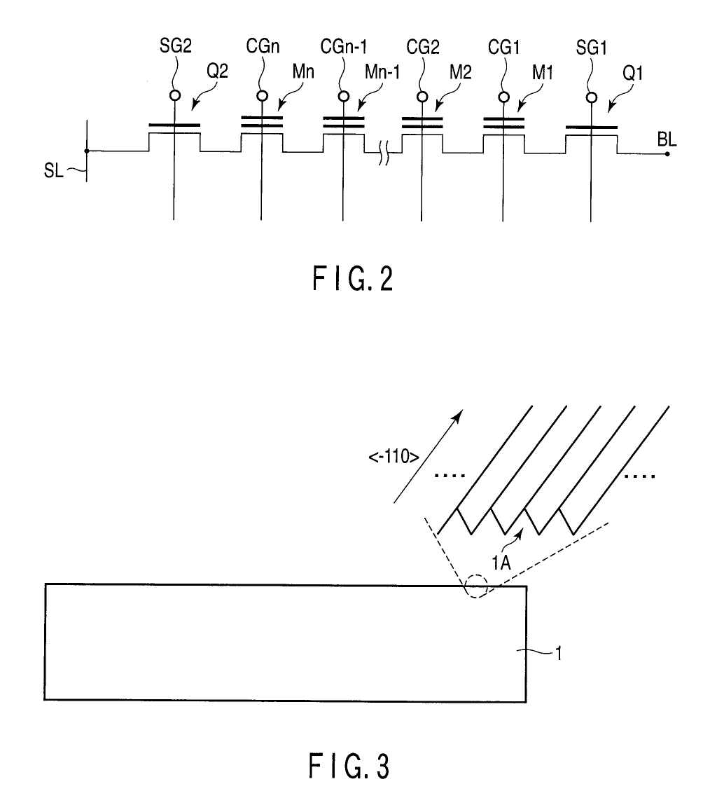

FIG. 1 is a plain view showing a part of a memory cell array in a NAND type flash memory. FIG. 2 is an equivalent circuit diagram of the memory cell array shown in FIG. 1.

In FIGS. 1 and 2, M1, M2, . . . , Mn−1, and Mn denote a plurality of memory cells. The plurality of memory cells M1, M2, . . . , Mn−1, and Mn constitute a NAND cell by being connected together in series so that the adjacent memory cells share a source/drain. A drain terminal of the NAND cell is connected to a bit line BL via a select transistor Q1. A source terminal of the NAND cell is connected to a source line SL via a select transistor Q2.

Each of the memory cells M1, M2, . . . , Mn−1, and Mn comprises MOSFET including a double gate structure (in which a CG electrode is stacked on a FG electrode via an insulating film) on a silicon substrate via a gate insulating film. Select transistors S1 and S2 comprise MOSFETs. The MOSFETs are formed on the same well substrate.

CG electrodes of the memory cells M1, M2, Mn−1, and Mn are connected to respective CGi lines (word lines) (i=1, 2, . . . , n−1, and n) disposed in the row direction of the memory cell array. Gate electrodes of select transistors Q1 and Q2 are connected to select gate lines SG1 and SG2 disposed in the row direction of the memory cell array. Each word line has a connection pad at one end which is connected to a peripheral circuit via a metal interconnection; this end is formed on an isolation film.

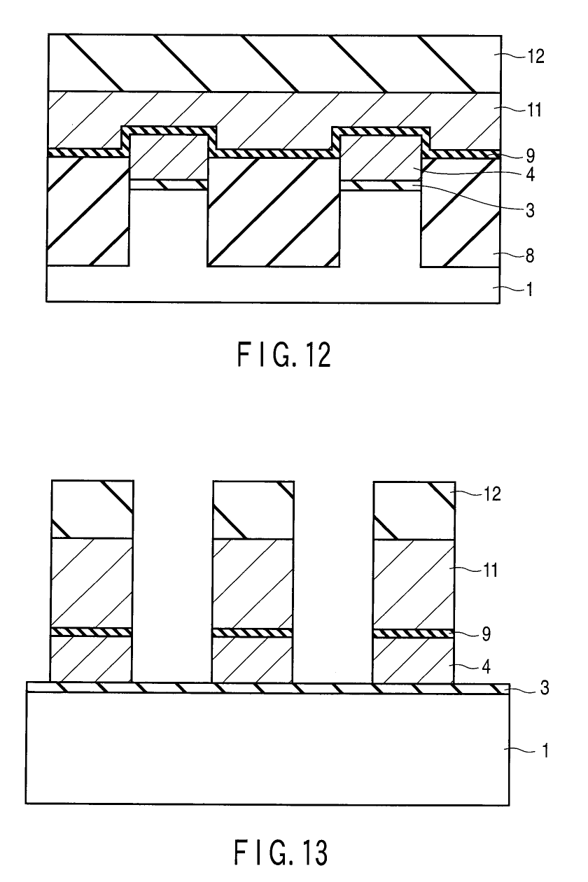

FIGS. 3 through 14 are cross-sectional views showing the method for manufacturing the NAND type flash memory of the present embodiment. FIGS. 3 through 12 are cross sectional views in a channel width direction and corresponding to cross sectional views along arrows A-A′ in FIG. 1. FIGS. 13 and 12 are cross sectional views in a channel length direction and corresponding to cross sectional views along arrows B-B′ in FIG. 1.

[FIG. 3]

A silicon substrate 1 having a main surface of (110) face is prepared. A pre-cleaning process for removing organic substances, metals and particles is performed on the silicon substrate 1. A chemical process based on RCA cleaning is popularly employed for the pre-cleaning process. Here, the following pre-cleaning process is performed. That is, a native oxide film is formed by ozone water, contaminating organic substances are removed, thereafter metals and particles are removed by DHF process.

The silicon substrate 1 that has been subjected to a pre-cleaning process is then subjected to rinse process using pure water for 3 minutes. The duration of the rinse process is not limited to 3 minutes, the duration may be in a range of 1 to 10 minutes.

By performing such a pure water rinse process, a groove structure 1A (a structure comprising a plurality of V-shaped grooves wherein the plurality of V-shaped grooves are continuously arranged) is formed in a <−110> direction of the main surface of the silicon substrate 1. The reason why the groove structure 1A is formed is as follows.

When the pure water rinse process is performed, the (110) surface that is the main surface of the silicon substrate 1 is etched by OH ions in pure water. On the other hand, the (111) surface of the silicon substrate 1 has a high resistance against alkali etching. As a result, as the etching of OH ions progresses, (111) facets are exposed. A plurality of grooves having the (111) facets as the side surfaces are continuously (successively) arranged, thereby the groove structure 1A is formed.

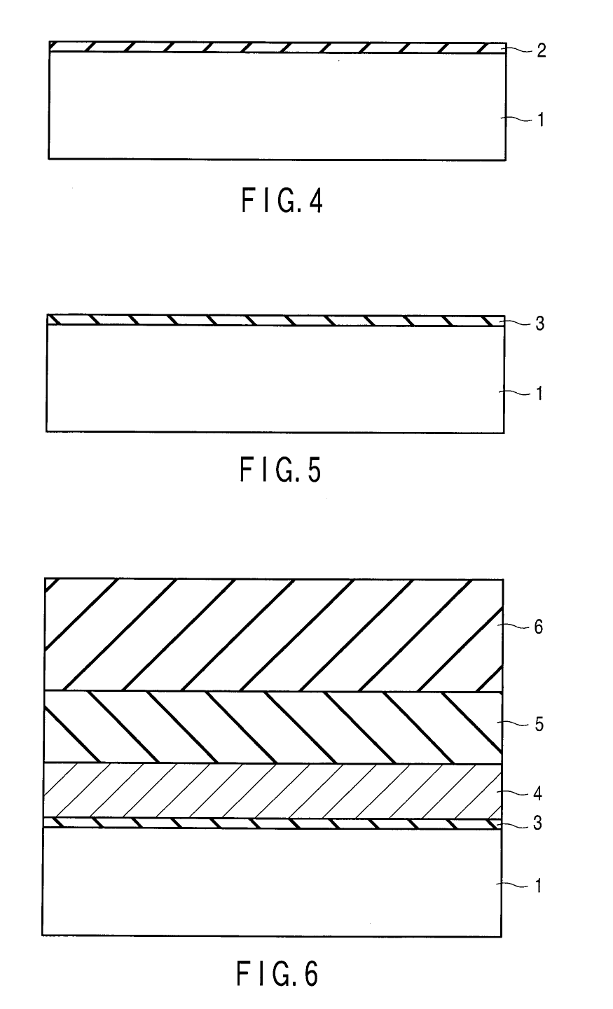

Such a groove structure 1A can be formed by process using alkali solution instead of pure water. The Si surface condition that is observed when Si is immersed in alkali solution is described in K. Sato et al., “Roughening of single-crystal silicon surface etched by KOH water solution,” Sensors and Actuators, vol. 73, 1999, pp. 122-130. Models are described in H. Akahori et al., “Atomic Order Flattening of Hydrogen-Terminated Si (110) substrate For Next Generation ULSI Devices,” in Ext. Abst. 2003, pp. 458-459.

[FIG. 4]

A silicon oxide film 2 is formed on the main surface of the silicon substrate 1. A silicon oxide film 2 is typically formed by radical oxidation process, thermal oxidation process or steam oxidation process.

[FIG. 5]

A silicon oxynitride film 3 as the tunnel insulating film is formed on the main surface of the silicon substrate 1 by nitriding the silicon oxide film 2 using nitriding gas such as NH₃ gas. Some other insulating film may be used as the tunnel insulating film.

[FIG. 6]

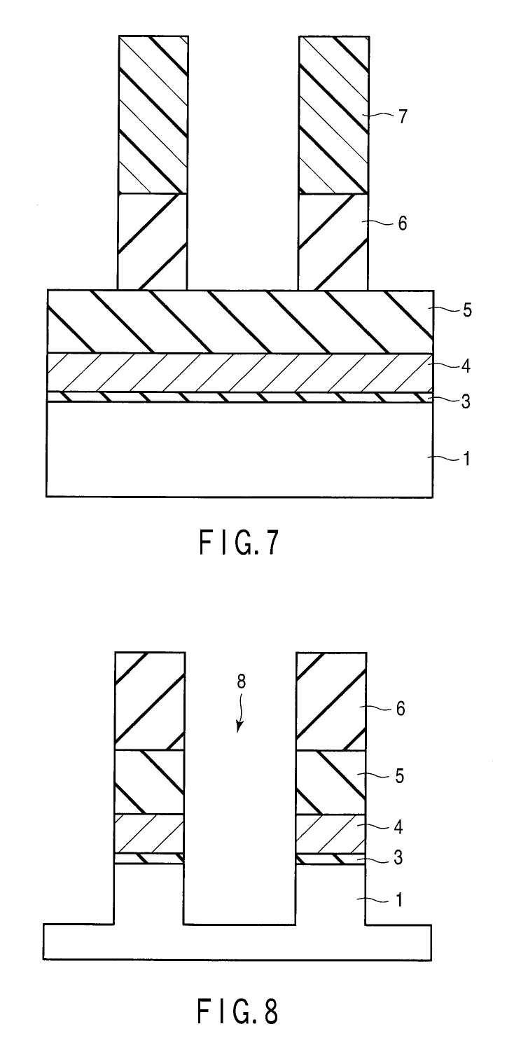

A polycrystalline silicon film 4, a silicon nitride film 5 and an oxide film are successively formed on the silicon oxynitride film 3. These films 4 through 6 are typically formed, for example, by CVD method. The polycrystalline silicon film 4 is used as the floating gate electrodes. The silicon nitride film and the oxide film 6 are used as a mask. The floating gate electrodes may comprises metal or metal silicide.

[FIG. 7]

A resist pattern 7 is formed on the oxide film 6 and the pattern of the resist pattern 7 is transferred onto the oxide film by etching the oxide film 6, using the resist pattern 7 as a mask.

[FIG. 8]

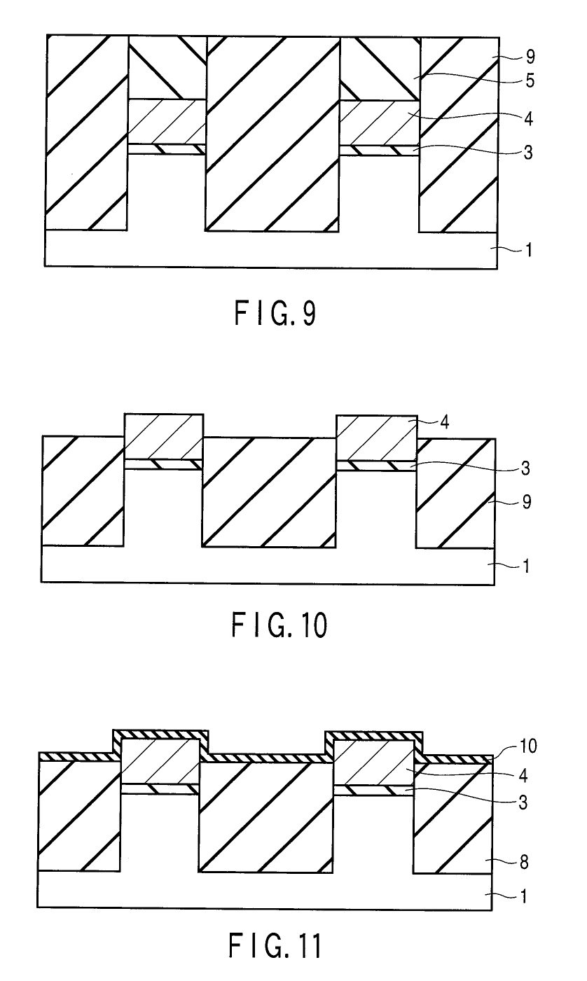

The resist pattern 7 is removed, and the trench 8 for isolation (STI) is formed by etching the silicon nitride film 5, the polycrystalline silicon film 4, the oxynitride film 3 and the silicon substrate 1 using the oxide film 6 as a mask. At this step, the shape of floating gate electrode in the channel width direction is determined. The floating gate electrode is formed of the polycrystalline silicon film 4.

[FIG. 9]

The inner walls of the trenches 8 are oxidized and an oxide film (not shown) is formed. An isolation insulating film 9 is formed on the entire surface to fill the trenches 8. Thereafter, the surface is planarized by CMP (chemical mechanical polishing) process, using the silicon nitride film 5 as a stopper.

While the isolation insulating film 9 is typically a silicon oxide film, any insulating film other than the silicon oxide film may be used so long as the silicon nitride film 5 can be used as the stopper. The isolation insulating film 9 is formed, for example, by plasma CVD method.

[FIG. 10]

The top portions of the polycrystalline silicon film 4 are exposed by selectively retreating the isolation insulating film 9 by way of a process that can etch the isolation insulating film 9 and the silicon nitride film 5 with a given selection ratio. The etching may be either wet etching or dry etching. Thereafter, the silicon nitride film 5 is selectively removed by wet process.

[FIG. 11]

An inter-gate electrode insulating film 10 is formed on the top and the side surfaces of the polycrystalline silicon film 4. When the floating gate electrodes and the control gate electrodes are formed of a polycrystalline silicon film, the inter-gate electrode insulating film 10 is referred to as inter-poly insulating film.

[FIG. 12]

A polycrystalline silicon film 11 to be processed into the control gate electrodes (word lines) and a silicon nitride film 12 are successively formed on the inter-gate electrode insulating film 10. The polycrystalline silicon film 11 and the silicon nitride film 12 are formed, for example, by LPCVD method. The control gate electrodes (word lines) may be formed of a conductive film other than the polycrystalline silicon film.

[FIG. 13]

A resist pattern (not shown) is formed on the silicon nitride film 12, the silicon nitride film 12 is etched using the resist pattern as a mask to transfer the pattern of the resist pattern onto the silicon nitride film 12, thereafter the resist pattern is removed.

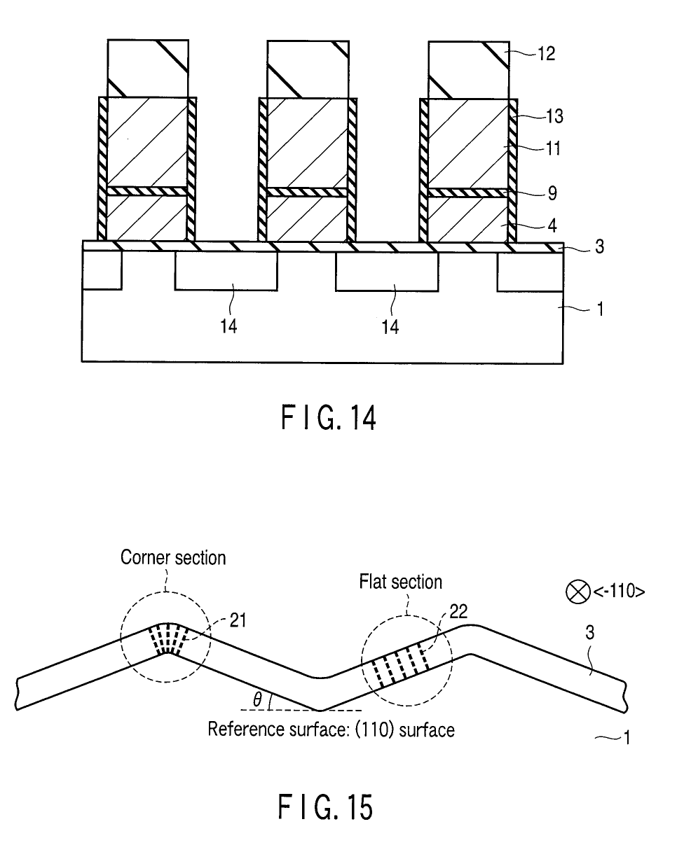

the polycrystalline silicon film 11, the inter-gate electrode insulating film 10 and the polycrystalline silicon film 4 are etched by using the silicon nitride film 12 as a mask. In this way, the control gate electrodes (word lines) 11 are formed, and the shape of the floating gate electrode 4 in the channel length direction is determined.

[FIG. 14]

A silicon oxide film 13 is formed on regions including the side surfaces of the gate structures 4, 9, 11. The silicon oxide film 13 is formed, for example, by thermal oxidation process or radical oxidation process. The purpose of forming the silicon oxide film 13 is to recover the gate edge from the damage which is caused at the time of RIE etching, and improve the breakdown voltage of the gate insulating film. This oxidation process is generally referred to as post-oxidation process and the silicon oxide film 13 formed by this process is referred to as post oxidation film.

After the forming the silicon oxide film 13, source/drain regions 14 are formed by ion implantation and thermal anneal. Thereafter, the NAND type flash memory is completed by way of known steps of forming an interlayer insulating film, forming a wiring layer and so on.

FIG. 15 is a schematic view showing electric lines of force 21 and 22 at corner sections (bent sections) and flat sections of the tunnel insulating film 13 when a negative high voltage (program voltage) is applied to the control gate electrode 11. As seen from FIG. 15, the electric lines of force 21 concentrate on a part of surface of the silicon substrate.

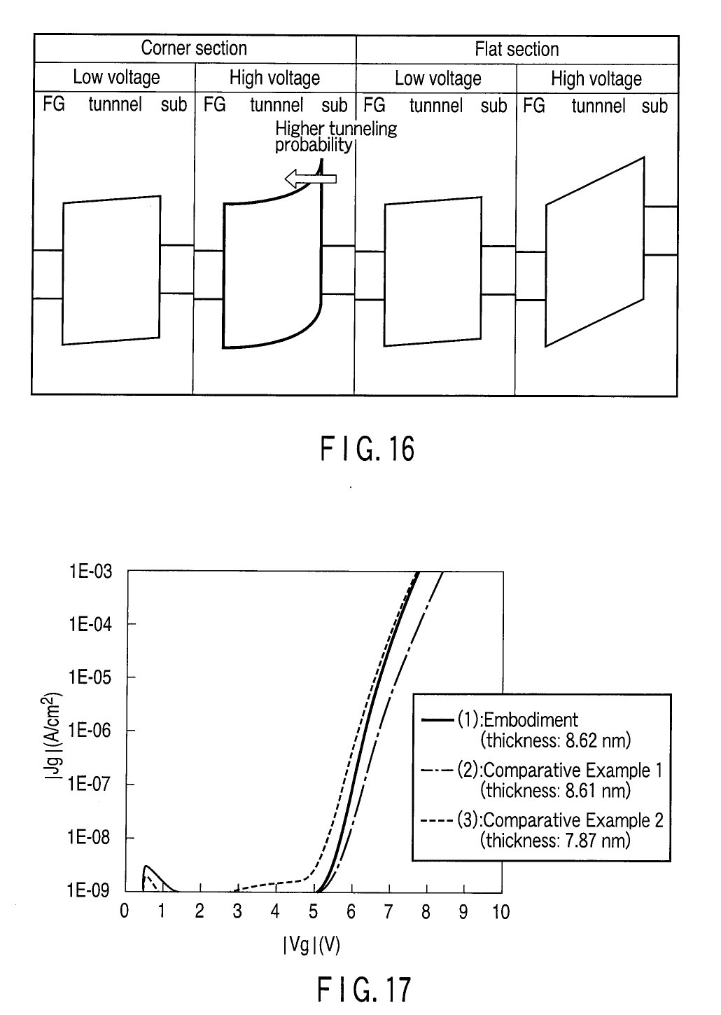

FIG. 16 is a view showing band structures of corner sections and flat sections of the tunnel insulating film 3 when a negative high voltage (program voltage) and negative low voltage are applied to the control gate electrode 11. In FIG. 16, sub denotes the silicon substrate 1, tunnel denotes the tunnel insulating film 3, and FG denotes the floating gate electrode (polycrystalline silicon film) 11.

From FIG. 16, it will be seen that the band structure of the flat section of the tunnel insulating film 3 is same as that of the flat section of the conventional insulating film, but the band structure of the corner section of the tunnel insulating film 3 is different from that of the corner section of the conventional insulating film. The band structure of the corner section can be explained as follows.

When the high positive voltage is applied to the control gate electrode 11, lines of electric force 21 are concentrated to a lower part of the corner section (the portion where the control gate electrode 11 contacts the silicon substrate 1). As a result, the barrier height of the corner section is practically lowered when the high positive voltage is applied, and the tunneling probability is heightened, thereby Fowler-Nordheim tunneling current (to be referred to as FN current hereinafter) is easy to flow.

On the other hand, when the low positive voltage is applied to the control gate electrode 11, the influence of concentration of the electric field is small at the corner section, and the bent of the band is small. As a result, the electrons sense approximately same level of barrier height at the corner section and the flat section.

It is noted that when the angle θ between the groove structure and the (110) surface (reference surface) is too large in FIG. 15, the dielectric breakdown by electric field concentration is apt to take place. Thus, the angle θ is preferably not greater than 20° (θ≦20°). In addition, the effect of the embodiment is obtained even if the angle θ is not higher than 8°, but from the point of view to flow the FN current efficiently, the angle θ is preferably not less than 5°. In the present embodiment, the angle θ is about 8 to 12°. The angle can be controlled by the conditions (time, temperature, PH) of the cleaning process such as the pure water rinse process that is performed before forming the tunnel insulating film 3.

FIG. 17 shows the FN current-voltage characteristic (Comparative Example 1, 2) observed when the tunnel insulating film 3 (thickness: 7.87 nm, 8.61 nm) is formed on a flat silicon substrate and the FN current-voltage characteristic (Embodiment) when the tunnel insulating film 3 (thickness: 8.62 nm) is formed on the silicon substrate 1 having the surface on which the groove structure 1A is formed.

From FIG. 17, it will be seen by comparing the FN current-voltage characteristic of the comparative example 1 (thickness: 8.61 nm) and the FN current-voltage characteristic of the embodiment (thickness: 8.62 nm), in the low voltage region, rising voltage of the FN current is about 5V in both comparative example 1 and the embodiment, but in the high voltage region, the embodiment shows higher rising voltage of the FN current than comparative example 1. That is, if the same thickness of tunnel insulating film is selected for both the embodiment and comparative example 1, the threshold voltage Vth is substantially same both in the embodiment and comparative example 1, but the FN current density obtained by the same applied voltage (>Vth) is clearly higher in the embodiment than in the comparative example 1.

In FIG. 17, the applied voltage needed to obtain the FN current density of 1×10⁻³ A/cm² is 8.3V in the comparative example 1 (thickness: 8.61 nm), whereas it is 7.6V in the embodiment (thickness: 8.62 nm). For the flat silicon substrate, it is necessary to reduce the thickness of the tunnel insulating film down to 7.87 nm as the comparative example 2 in order to obtain the current density of 1×10⁻³ A/cm² at 7.6V as the embodiment. However, the charge retention characteristic of the comparative Example 2 is degraded due to the reduction of the thickness of the tunnel insulating film.

In this way, according to the present embodiment, concerning the low voltage region, the same FN current-voltage characteristic is obtained as in the case of using the tunnel insulating film of 8.61 nm thickness, on the other hand, concerning the high voltage region, the same FN current-voltage characteristic is obtained as in the case of using the thinner tunnel insulating film of 7.87 nm thickness. That is, the current-voltage characteristic, which suppresses the increasing of the FN current in the low voltage region (the charge retention characteristic is maintained) and increases the FN current in the high voltage region, is obtained. Thereby, according to the present embodiment, even if the tunnel insulating film 3 having the thickness which suppresses the charge retention characteristic from being degraded is used (without relying on reduction of the thickness of the tunnel insulating film), the semiconductor device comprising the nonvolatile memory cells which enable the program voltage to be lowered is realized.

The peak (top) to peak (top) distance of the groove structure 1A (pp distance) that provides an improved tunnel characteristic is about a few nm. In the embodiment, the pp distance is 5 nm to 15 nm. The pp distance can be controlled by adjusting the duration of the pure water rinse time in the pre-cleaning process that is performed before forming the tunnel insulating film 3.

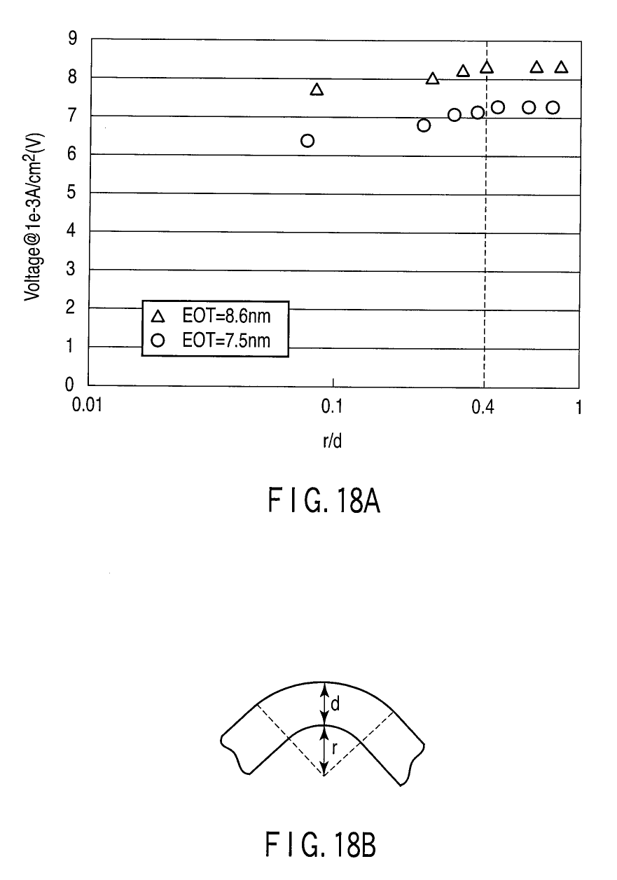

FIG. 18A show relationships between ratio (r/d) and applied voltage when FN current density reaches 1×10⁻³ A/cm². Here, r is a curvature radius of a protrusion portion (substrate) under a corner portion of the tunnel insulating film 3, d is the effective thickness of the oxide film (EOT: equivalent oxide thickness) of the tunnel insulating film 3 as shown in FIG. 18B.

From FIG. 18A, in each case of d is 7.5 nm and d is 8.6 nm, it will be seen that the applied voltage is sufficiently reduced by setting r/d less than 0.4 (r/d<0.4).

In addition, the control gate voltage for flowing the FN current flow having required current density can be reduced by setting r/d less than predetermined level even if FN current density is other than 1×10⁻³ A/cm²

It will be understood that the present invention is not limited to the embodiment mentioned above. and the EOT is other 7.5 nm and 8.6 nm.

For example, in the above mentioned embodiment, the silicon substrate whose main surface is (110) surface is used, the similar groove structure can be formed by using a silicon substrate whose main surface (crystal surface) is oriented substantially equivalent to the (110) surface orientation from a crystallographically point of view, and similar effects are obtained. Specifically, the main surfaces is (551) surface, (311) surface, (221) surface, (553) surface, (335) surface, (112) surface, (115) surface or (117) surface.

According to FIG. 2 of Kazuo Sato et al., “Sensors and Actuators 73 (1999)” (P122-130), a surface shape having streaks running in a direction of <−110> is obtained when the (110) surface is subjected to an alkali etching process. The region that can obtain the similar surface shape as the (110) surface is a surface turned by 0 to 12° toward the direction of <110> such as (551) surface that is turned by 8°. The similar surface shape can be obtained to a surface that is turned up to 1° toward the direction of <−110>. Thus, the surface orientation that shows the surface roughness same as the (110) surface shown in FIG. 2 of the above-cited paper is intrinsically included in the (110) surface orientation.

The similar effect can be obtained in a case of (100) surface by controlling the surface roughness. The method for increasing the surface roughness is disclosed in the reference (T. Ohmi et al., “Dependence of Surface Micro roughness of CZ, FZ and EPI Wafers on Wet Chemical Processing”, J. Electrochem. Soc. Vol. 139, No. 8. pp. 2133-2142 (1992)). This reference shows that the shape of (100) surface can be controlled by changing NH₄OH concentration at the time of performing the alkali cleaning (APM Cleaning using mixed solution of NH₄OH, H₂, O₂, H₂O) which is performed forming the gate insulating film. Thereby, a structure including a plurality of protrusion portions with sharp pointed ends (concavity and convexity structure) can be realized. The relationship between the radius of curvature r of the surface protrusions and the tunnel insulating film thickness d illustrated in FIG. 18 can be applied to the (100) surface as well as to the (110) surface.

In addition, the above embodiment is described in terms of NAND type flash memory cells (floating gate type nonvolatile memory cells), the present invention is also applicable to nonvolatile memory cells of other type such as MONOS (Metal-Oxide-Nitride-Oxide-Semiconductor) type nonvolatile memory cells using a charge accumulation layer as the floating gate.

In addition, no reference is made to the nodes of nonvolatile memory cells in the above embodiment, the present invention is effective to the nodes not larger than 20 nm that can hardly be handled with the conventional technology.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a silicon substrate having a main surface, the main surface including a region in which a groove structure or a concavity and convexity structure is formed; and
a nonvolatile memory cell provided on the main surface of the silicon substrate, the nonvolatile memory cell including a first insulating film as a tunnel insulating film provided on the region, a charge storage layer provided on the first insulating film, a second insulating film provided on the charge storage layer, a control gate provided on the second insulating film.

2. The semiconductor device according to claim 1, wherein the main surface has a crystal surface, and the crystal surface is (110) surface, (551) surface, (311) surface, (221) surface, (553) surface, (335) surface, (112) surface, (115) surface or (117) surface.

3. The semiconductor device according to claim 1, wherein the groove structure is a structure comprising a plurality of V-shaped grooves wherein the plurality of V-shaped grooves are continuously arranged, and the convexity structure is a structure comprising a plurality of protrusion portions with sharp pointed ends.

4. The semiconductor device according to claim 2, wherein the groove structure is a structure comprising a plurality of V-shaped grooves wherein the plurality of V-shaped grooves are continuously arranged, and the convexity structure is a structure comprising a plurality of protrusion portions with sharp pointed ends.

5. The semiconductor device according to claim 1, wherein a inequality r/d<0.4 is satisfied, where r is a curvature radius of the groove structure or the concavity and convexity structure, and d is a thickness of the first insulating film.

6. The semiconductor device according to claim 2, wherein a inequality r/d<0.4 is satisfied, where r is a curvature radius of the groove structure or the concavity and convexity structure, and d is a thickness of the first insulating film.

7. The semiconductor device according to claim 3, wherein a inequality r/d<0.4 is satisfied, where r is a curvature radius of the groove structure or the concavity and convexity structure, and d is a thickness of the first insulating film.

8. The semiconductor device according to claim 4, wherein a inequality r/d<0.4 is satisfied, where r is a curvature radius of the groove structure or the concavity and convexity structure, and d is a thickness of the first insulating film.

9. The semiconductor device according to claim 1, wherein the nonvolatile memory cell is a floating gate type nonvolatile memory cell.

10. A method for manufacturing a semiconductor device comprising:
forming a groove structure or a concavity and convexity structure on a surface of a silicon substrate; and
forming a nonvolatile memory cell on the main surface of the silicon substrate, the nonvolatile memory cell including a first insulating film as a tunnel insulating film provided on the region, a charge storage layer provided on the first insulating film, a second insulating film provided on the charge storage layer, a control gate provided on the second insulating film.

11. The method for manufacturing the semiconductor device according to claim 10, wherein the main surface has predetermined crystal surface, and the forming the groove structure or the concavity and convexity structure on the surface of the silicon substrate includes performing wet treatment to the main surface having the predetermined crystal surface.

12. The method for manufacturing the semiconductor device according to claim 10, wherein the predetermined crystal surface is (110) surface, (551) surface, (311) surface, (221) surface, (553) surface, (335) surface, (112) surface, (115) surface or (117) surface.

13. The method for manufacturing the semiconductor device according to claim 11, wherein the wet treatment is treatment using pure water or treatment using alkali solution.

14. The method for manufacturing the semiconductor device according to claim 12, wherein the wet treatment is treatment using pure water or treatment using alkali solution.

15. The method for manufacturing the semiconductor device according to claim 10, further comprising cleaning the silicon substrate before performing the wet treatment.

16. The method for manufacturing the semiconductor device according to claim 12, wherein the forming the first insulating film includes forming a silicon oxide film, and nitriding the silicon oxide film.
